(19) United States
(12) Patent Application Publication
(10) Pub. No.: US 2026/0305239 A1
(43) Pub. Date: Oct. 1, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventor: Nozomu NAKAGAWA, Kyoto (JP)

(21) Appl. No.: 19/478,983

(22) PCT Filed: Apr. 5, 2024
(86) PCT No.: PCT/JP2024/014088

§ 371 Date: Oct. 27, 2025

(30) Foreign Application Priority Data
Apr. 28, 2023 (JP) 2023-074362

(51) Int. Cl. H10P 72/30; H10P 72/00

(52) U.S. Cl. CPC H10P 72/3211; H10P 72/0408; H10P 72/0416; H10P 72/0468; H10P 72/3402

(57) ABSTRACT

Provided is a substrate processing apparatus having high drying processing performance and high throughput while making substrate processing exactly the same. A predetermined number of substrates whose posture has been changed into a vertical orientation by an orientation changing mechanism are sequentially immersed in a chemical liquid processing tank and a liquid processing tank, the predetermined number of substrates in the vertical orientation that have been subjected to liquid processing for a predetermined time are sequentially taken out from the chemical liquid processing tank and the liquid processing tank and conveyed to the orientation changing mechanism, the orientation of the predetermined number of substrates in the vertical orientation that have been subjected to the liquid processing is changed into a horizontal orientation by the orientation changing mechanism, and the substrates in the horizontal orientation are subjected to drying processing by a single wafer substrate processing chamber. According to the present invention, the predetermined number of substrates unloaded from a carrier are sequentially conveyed and subjected to liquid processing and drying processing. Since the substrates are sequentially immersed in the liquid processing tank without waiting for a long time before the liquid processing, the processing histories of the substrates are equalized, and a highly reliable substrate processing apparatus can be provided.

### TECHNICAL FIELD

The present invention relates to a substrate processing apparatus and a substrate processing method for continuously performing a series of processing while changing an orientation of a substrate. Examples of the substrate include various substrates such as a semiconductor substrate, a substrate for a flat panel display (FPD) such as a liquid crystal display or an organic electroluminescence (EL) display device, a glass substrate for a photomask, and a substrate for an optical disk.

### BACKGROUND ART

The apparatus of Patent Literature 1 includes a single wafer processing unit related to single wafer type substrate processing on the back side of a loading/unloading unit that loads and unloads a cassette. The single wafer processing unit processes a substrate in a horizontal orientation. The apparatus also includes a batch processing unit related to batch type substrate processing on the further back side of the single wafer processing unit. The batch processing unit processes a substrate whose orientation has been changed into a vertical orientation. Thus, according to this apparatus configuration, the substrate taken out from the cassette in the loading/unloading unit first passes through the single wafer processing unit and is conveyed to the batch processing unit. The substrate subjected to the batch processing by the batch processing unit is returned to the single wafer processing unit. Then, the single wafer processing unit performs single wafer processing on the batch-processed substrate. A series of substrate processing is realized by an apparatus in which the batch type module and a single wafer type module are integrated.

The apparatus has a configuration having both an advantage of batch type substrate processing capable of collectively processing a plurality of substrates and shortening the processing time for the substrates and an advantage of single wafer type substrate processing capable of processing the substrates one by one and performing highly reliable substrate processing.

### CITATION LIST

### Patent Literature

Patent Literature 1: JP 2021-64654 A

### SUMMARY OF INVENTION

### Technical Problem

However, the apparatus described above cannot perform exactly the same substrate processing on a plurality of substrates stored in the cassette. According to the conventional configuration, the substrates taken out one by one from the cassette pass through the single wafer processing unit and are immersed in a standby tank in the order of conveyance. Then, the batch processing starts when all the substrates in the cassette are accumulated in the standby tank. Thus, the substrate first taken out from the cassette is subjected to batch processing after being immersed in the standby tank for a long time until all subsequent substrates arrive at the standby tank. On the other hand, the substrate taken out from the cassette in the last place is subjected to batch processing shortly after being immersed in the standby tank. The immersion time of the plurality of substrates subjected to batch processing in the standby tank is different between the substrates like this. That is, according to the conventional apparatus, exactly the same substrate processing cannot be performed on all the substrates stored in the cassette. Such circumstances give rise to individuality of each device to be manufactured and affect the quality of the device.

Thus, to make the substrate processing exactly the same, it is necessary to perform the substrate processing using a substrate processing apparatus capable of performing only batch processing or a substrate processing apparatus capable of only performing a single wafer processing apparatus as in the conventional technology. Since the conventional batch processing apparatus cannot perform drying processing on substrates one by one, there is a problem that the performance of the drying processing is inferior to that of the single wafer processing apparatus. On the other hand, the conventional single wafer processing apparatus is not good at chemical liquid processing that takes a long time for processing. This is because one substrate continues to occupy the substrate processing chamber included in the single wafer processing apparatus as long as the processing is performed, and thus, the throughput is significantly reduced.

The present invention has been made in view of such circumstances, and an object of the present invention is to provide a substrate processing apparatus having high performance and high throughput of drying processing while performing exactly the same substrate processing.

### Solution to Problem

To solve the problem described above, the present invention has the following configurations.
(1) A substrate processing apparatus that continuously performs a series of processing while changing an orientation of a substrate, the substrate processing apparatus including: a carrier placement shelf on which a carrier that stores a plurality of substrates in a horizontal orientation at predetermined intervals in a vertical direction is placed; an indexer robot that takes out and stores a predetermined number of substrates from and in the carrier; an orientation changing mechanism that changes the orientation of a predetermined number of substrates into a horizontal orientation and a vertical orientation; a liquid processing tank in which a plurality of substrates in the vertical orientation are arrayed in a horizontal direction and immersed in a processing liquid; a single wafer substrate processing chamber that performs drying processing on substrates in the horizontal orientation one by one by rotating the substrates in the horizontal orientation around a vertical axis; a first substrate conveyance mechanism that conveys the predetermined number of substrates in the horizontal orientation between the indexer robot, the orientation changing mechanism, and the single wafer substrate processing chamber; a second substrate conveyance mechanism that conveys the predetermined number of substrates in the vertical orientation between the orientation changing mechanism and the liquid processing tank; and a control unit, wherein the control unit controls the indexer robot to take out the predetermined number of substrates from the carrier; the control unit controls the first substrate conveyance mechanism to convey the predetermined number of substrates taken out from the carrier to the orientation changing mechanism, the control unit controls the orientation changing mechanism to change the orientation of the predetermined number of substrates in the horizontal orientation into the vertical orientation, the control unit controls the second substrate conveyance mechanism to sequentially immerse the predetermined number of substrates whose orientation has been changed into the vertical orientation in the liquid processing tank, the control unit controls the second substrate conveyance mechanism to sequentially take out the predetermined number of substrates in the vertical orientation that have been subjected to liquid processing for a predetermined time from the liquid processing tank and convey the substrates to the orientation changing mechanism, the control unit controls the orientation changing mechanism to change the orientation of the predetermined number of substrates in the vertical orientation that have been subjected to liquid processing into the horizontal orientation, the control unit controls the first substrate conveyance mechanism to convey the predetermined number of substrates in the horizontal orientation to the single wafer substrate processing chamber, the control unit controls the single wafer substrate processing chamber to rotate the substrates in the horizontal orientation about a vertical axis to dry the substrates one by one, the control unit controls the first substrate conveyance mechanism to cause the indexer robot to convey the predetermined number of substrates in the horizontal orientation that have been subjected to drying processing, and the control unit controls the indexer robot to store the predetermined number of substrates in the horizontal orientation that have been subjected to drying processing in the carrier.

[Operation and Effect] According to the above-described configuration, the predetermined number of substrates in the horizontal orientation taken out from the carrier are conveyed to the orientation changing mechanism. The predetermined number of substrates whose orientation has been changed into a vertical orientation by the orientation changing mechanism are sequentially immersed in the liquid processing tank. The predetermined number of substrates in the vertical orientation that have been subjected to the liquid processing for a predetermined time are sequentially taken out from the liquid processing tank and conveyed to the orientation changing mechanism. The orientation of the predetermined number of substrates in the vertical orientation that have been subjected to the liquid processing is changed into a horizontal orientation by the orientation changing mechanism. The predetermined number of substrates in the horizontal orientation are conveyed to the single wafer substrate processing chamber. The predetermined number of substrates in the horizontal orientation that have been subjected to the drying processing by the single wafer substrate processing chamber are conveyed by the indexer robot and stored in the carrier. Thus, according to the present invention, the predetermined number of substrates conveyed from the carrier are sequentially conveyed and subjected to liquid processing and drying processing. Since the substrates are sequentially immersed in the liquid processing tank without waiting for a long time before the liquid processing, the processing histories of the substrates are equalized, and a highly reliable substrate processing apparatus can be provided. In addition, in the liquid processing tank, because a plurality of substrates in a vertical orientation are arrayed in a horizontal direction and immersed in the processing liquid, the plurality of substrates can be concurrently subjected to liquid processing, and a substrate processing apparatus with a high throughput can also be realized.

The following inventions are also disclosed in the present specification.
(2) The substrate processing apparatus according to (1), wherein the indexer robot is provided in the indexer block, the orientation changing mechanism is provided in the orientation changing block, the liquid processing tank is provided in the vertically-oriented substrate processing block, the single wafer substrate processing chamber is provided in the horizontally-oriented substrate processing block, the indexer block is adjacent to the carrier placement shelf, the horizontally-oriented substrate processing block is adjacent to the indexer block on a side opposite to a side on which the carrier placement shelf is in contact, the orientation changing block is adjacent to the horizontally-oriented substrate processing block on a side opposite to a side on which the indexer block is in contact, and the vertically-oriented substrate processing block is adjacent to the orientation changing block on a side opposite to a side on which the horizontally-oriented processing block is in contact.

[Operation and Effect] The substrate processing apparatus described in (2) includes an indexer block provided with an indexer robot, an orientation changing block provided with an orientation changing mechanism, a vertically-oriented substrate processing block provided with a liquid processing tank, and a horizontally-oriented substrate processing block provided with a single wafer substrate processing chamber. The substrate processing apparatus is configured by arraying a carrier placement shelf, the indexer block, the horizontally-oriented substrate processing block, the orientation changing block, and the vertically-oriented substrate processing block in this order. According to such a configuration, the substrate conveyance in the present invention can be efficiently performed. This is because the blocks are arrayed in the order in which the substrates are conveyed. In addition, because the carrier placement shelf and the indexer block can be placed away from the liquid processing tank, it is possible to reduce the influence of the liquid atmosphere on the carrier placement shelf and the indexer block.
(3) The substrate processing apparatus according to (2), wherein a substrate handling mechanism and a horizontally-oriented substrate conveyance mechanism are provided as the first substrate conveyance mechanism, the substrate handling mechanism delivers the predetermined number of substrates between the indexer robot and the horizontally-oriented substrate processing block, the horizontally-oriented substrate conveyance mechanism is provided in the orientation changing block, and delivers the predetermined number of substrates between the horizontally-oriented substrate processing block and the orientation changing mechanism, when sending the substrates to the liquid processing tank, the control unit controls the substrate handling mechanism to convey the predetermined number of substrates taken out from the carrier by the indexer robot to the horizontally-oriented substrate processing block, and the control unit controls the horizontally-oriented substrate conveyance mechanism to cause the orientation changing mechanism to convey the predetermined number of substrates conveyed to the horizontally-oriented substrate processing block, when returning the substrates from the liquid processing tank, the control unit controls the horizontally-oriented substrate conveyance mechanism to convey the predetermined number of substrates whose orientation has been changed into the horizontal orientation by the orientation changing mechanism to the single wafer substrate processing chamber, and the control unit controls the substrate handling mechanism to cause the indexer robot to convey the predetermined number of substrates in the horizontal orientation that have been subjected to drying processing by the single wafer substrate processing chamber.

[Operation and Effect] According to the substrate processing apparatus described in (3), the substrate handling mechanism conveys an unprocessed substrate before liquid processing and a substrate that has been subjected to drying processing, and the horizontal orientation substrate conveyance mechanism conveys a substrate after liquid processing and before drying processing. Thus, the dried substrate and the substrate wetted by the liquid are conveyed by different conveyance mechanisms. Thus, the dried unprocessed substrate is not conveyed by the wet conveyance mechanism, and a part of the substrate does not become wet before liquid processing. In addition, according to the present configuration, the substrate after drying processing is not conveyed by the wet conveyance mechanism, and a part of the substrate does not become wet again.
(4) The substrate processing apparatus according to (2), wherein the orientation changing block includes: a first substrate standby tank for a forward path in which the predetermined number of substrates in the vertical orientation before liquid processing are immersed in pure water; a second substrate standby tank for a return path in which the predetermined number of substrates in the vertical orientation after liquid processing are immersed in pure water; and a substrate lifting mechanism capable of delivering the substrates between the orientation changing mechanism and the second substrate conveyance mechanism and capable of lifting the predetermined number of substrates in the vertical orientation between a delivery position of the substrate and a standby position in the first and second substrate standby tanks, when sending the substrates to the liquid processing tank, the control unit controls the substrate lifting mechanism to cause the predetermined number of substrates whose orientation has been changed into the vertical orientation by the orientation changing mechanism to be immersed in pure water in the first substrate standby tank and stand by, and when returning the substrates from the liquid processing tank, the control unit controls the substrate lifting mechanism to receive the predetermined number of substrates in the vertical orientation that have been subjected to liquid processing from the second substrate conveyance mechanism, and causes the predetermined number of substrates in the vertical orientation to be immersed in pure water in the second substrate standby tank and stand by.

[Operation and Effect] The substrate processing apparatus described in (4) includes a first substrate standby tank for a forward path in which a substrate in a vertical orientation before liquid processing is immersed in pure water, and a second substrate standby tank for a return path in which a substrate in a vertical orientation after liquid processing is immersed in pure water. Then, the substrate processing apparatus of the present configuration includes a substrate lifting mechanism that lifts and lowers the substrate between the delivery position of the substrate and the standby positions in the first and second substrate standby tanks. With such a configuration, it is possible to prevent the substrate from being left on standby in the air before and after the liquid processing and the substrate from being inadvertently dried.
(5) The substrate processing apparatus according to (2), wherein the vertically-oriented substrate processing block includes, as the liquid processing tank, a chemical liquid processing tank containing a chemical liquid and a pure water processing tank containing pure water, the control unit controls the second substrate conveyance mechanism to sequentially immerse the predetermined number of substrates whose orientation has been changed into the vertical orientation in the chemical liquid processing tank, the control unit controls the second substrate conveyance mechanism to sequentially take out the predetermined number of substrates in the vertical orientation that have been subjected to chemical liquid processing for a predetermined time from the chemical liquid processing tank, and then convey the substrates to the pure water processing tank and sequentially immerse the substrates in the pure water processing tank, and the control unit controls the second substrate conveyance mechanism to sequentially take out the predetermined number of substrates in the vertical orientation that have been subjected to pure water processing and convey the substrates to the orientation changing block.

[Operation and Effect] According to the substrate processing apparatus described in (5), a chemical liquid processing tank containing a chemical liquid and a pure water processing tank containing pure water are provided as the liquid processing tanks. With this configuration, the substrate on which the substrate processing using the chemical liquid has been performed can be reliably rinsed with pure water. Also in the pure water processing, it is not necessary to perform batch processing in which a predetermined number of substrates are sequentially put on standby to form a lot and the lot is immersed in pure water. In this manner, in the present invention, the processing time for the plurality of substrates in a vertical orientation is not different between the substrates, and it is possible to provide a substrate processing apparatus capable of producing a highly reliable device.
(6) The substrate processing apparatus according to (2), wherein the horizontally-oriented substrate processing block includes a stacked body formed by stacking the single wafer substrate processing chambers in a vertical direction. [Operation and Effect] According to the substrate processing apparatus described in (6), the horizontally-oriented substrate processing block includes a stacked body formed by stacking single wafer substrate processing chambers in a vertical direction. With this configuration, horizontally-oriented substrate processing can be performed in parallel in a plurality of substrate processing chambers, and thus, a substrate processing apparatus with a high throughput can be provided.
(7) The substrate processing apparatus according to (2), wherein the single wafer substrate processing chamber rotates the substrates in the horizontal orientation about a vertical axis and performs chemical liquid processing on the substrates one by one before the drying processing.

[Operation and Effect] According to the substrate processing apparatus described in (7), preliminary chemical liquid processing can be performed before the substrate processing related to the liquid processing tank. This makes it possible to perform suitable substrate processing according to the device to be produced.
(8) The substrate processing apparatus according to (2), the substrate processing apparatus including: a first region that is adjacent to the indexer block on a side opposite to a side on which the carrier placement shelf is in contact and extends in a direction away from the indexer block; and a second region facing the first region, adjacent to the indexer block, and extending in a direction away from the indexer block, wherein in the first region, the first horizontally-oriented substrate processing block, the first orientation changing block, and the first vertically-oriented substrate processing block are disposed linearly, in the second region, the second horizontally-oriented substrate processing block, the second orientation changing block, and the second vertically-oriented substrate processing block are disposed linearly, the substrate handling mechanism is disposed in a central region between the first region and the second region and in contact with the indexer block, and the substrate handling mechanism delivers the substrates to and from each of the first horizontally-oriented substrate processing block and the second horizontally-oriented substrate processing block.

[Operation and Effect] The substrate processing apparatus described in (8) includes two vertically-oriented substrate processing blocks, in which an orientation changing block is provided for each vertically-oriented processing block, and a horizontally-oriented substrate processing block is provided for each orientation changing block. Then, the substrate handling mechanism is provided in a central region between the line of the first horizontally-oriented substrate processing block, the first orientation changing block, and the first vertically-oriented processing block and the line of the second horizontally-oriented substrate processing block, the second orientation changing block, and the second vertically-oriented processing block. The substrate handling mechanism delivers substrates to and from both the first horizontally-oriented substrate processing block and the second horizontally-oriented substrate processing block. With this configuration, the number of substrates that can be processed at a time can be increased, and a substrate processing apparatus with a high throughput can be provided. In addition, because the substrate handling mechanism is shared by the first horizontally-oriented substrate processing block and the second horizontally-oriented substrate processing block, the apparatus having a reduced size can be realized.
(9) A substrate processing method for continuously performing a series of processing while changing an orientation of a substrate, the substrate processing method including: a first orientation changing process of changing an orientation of a predetermined number of substrates from a horizontal orientation to a vertical orientation; an immersion liquid processing process of sequentially immersing the predetermined number of substrates in the vertical orientation in a processing liquid in a liquid processing tank to perform liquid processing with a plurality of substrates in the vertical orientation being arrayed in a horizontal direction in the liquid processing tank; a second orientation changing process of sequentially taking out the predetermined number of substrates in the vertical orientation that have been subjected to the liquid processing for a predetermined time from the liquid processing tank and changing the orientation of the predetermined number of substrates from the vertical orientation to the horizontal orientation; and a single wafer substrate drying processing process of rotating the substrates in the horizontal orientation about a vertical axis to dry the substrates one by one.

[Operation and Effect] The substrate processing method described (9) includes a first orientation changing process of changing the orientation of a predetermined number of substrates in a horizontal orientation into a vertical orientation, an immersion liquid processing process of sequentially immersing the predetermined number of substrates in the vertical orientation in a processing liquid in a liquid processing tank, a second orientation changing process of sequentially taking out the predetermined number of substrates in the vertical orientation that have been subjected to liquid processing for a predetermined time from the liquid processing tank and changing the orientation of the predetermined number of substrates in the vertical orientation into the horizontal orientation, and a single wafer substrate drying processing process of drying the substrates in the horizontal orientation one by one. With this configuration, it is not necessary to perform batch processing of sequentially putting a predetermined number of substrates on standby to form a lot and perform liquid processing on the lot. Thus, the processing histories of the substrates become uniform, and highly reliable processing can be performed. In addition, because a plurality of substrates can be immersed in the liquid processing tank and concurrently processed, a high throughput can be realized.
(10) The substrate processing method according to (9), wherein the immersion liquid processing process includes: a chemical liquid processing process of sequentially immersing the predetermined number of substrates in the vertical orientation in the chemical liquid in the chemical liquid processing tank to perform chemical liquid processing with a plurality of substrates in the vertical orientation being arrayed in the horizontal direction; and a pure water processing process of immersing the predetermined number of substrates in the vertical orientation taken out from the chemical liquid processing tank into pure water in a pure water processing tank to perform pure water processing with a plurality of substrates in the vertical orientation being arrayed in the horizontal direction.

[Operation and Effect] The substrate processing method described in (10) includes a chemical liquid processing process in which a plurality of substrates in a vertical orientation are arrayed in a horizontal direction and subjected to chemical liquid processing, and a pure water processing process in which a plurality of substrates in the vertical orientation are arrayed in a horizontal direction and subjected to pure water processing after the chemical liquid processing process. With this configuration, the substrate processing using the chemical liquid and the substrate processing using pure water can be continuously performed.
(11) The substrate processing method according to (9), the method further including a single wafer substrate chemical liquid processing process of processing substrates one by one by rotating the substrates in the horizontal orientation about a vertical axis before the single wafer substrate drying processing process.

[Operation and Effect] According to the substrate processing method described in (11), preliminary chemical liquid processing can be performed before the substrate processing according to the immersion liquid processing process. This makes it possible to perform suitable substrate processing according to the device to be produced.

### ADVANTAGEOUS EFFECTS OF INVENTION

According to the present invention, a predetermined number of substrates whose orientation has been changed into a vertical orientation by the orientation changing mechanism are sequentially immersed in the liquid processing tank, the predetermined number of substrates in the vertical orientation that have been subjected to liquid processing for a predetermined time are sequentially taken out from the liquid processing tank and conveyed to the orientation changing mechanism, the orientation of the predetermined number of substrates in the vertical orientation that have been subjected to the liquid processing is changed into a horizontal orientation by the orientation changing mechanism, the predetermined number of substrates in the horizontal orientation are conveyed to a single wafer substrate processing chamber, and substrate drying processing is performed by the single wafer substrate processing chamber. According to the present invention, there is no need to perform batch processing in which a predetermined number of substrates taken out from a carrier are sequentially put on standby to form a lot and liquid processing is performed on the lot. In this manner, in the present invention, the processing time for the substrates in a vertical orientation is not different between the substrates, and the processing history of each substrate becomes uniform. Thus, a highly reliable device can be produced. In addition, because a plurality of substrates in a vertical orientation can be concurrently processed in a liquid processing tank, a high throughput can be realized.

### BRIEF DESCRIPTION OF DRAWINGS

FIG. 1 is a plan view for describing an overall configuration of a substrate processing apparatus according to Example.

FIG. 2 is a schematic diagram illustrating a horizontal substrate conveyance mechanism according to Example.

FIG. 3 is a schematic diagram illustrating an orientation changing mechanism according to Example.

FIG. 4 is a schematic diagram illustrating the orientation changing mechanism according to Example.

FIG. 5 is a schematic diagram illustrating a vertically-oriented substrate conveyance mechanism according to Example.

FIG. 6 is a schematic diagram illustrating the vertically-oriented substrate conveyance mechanism according to Example.

FIG. 7 is a schematic diagram illustrating the vertically-oriented substrate conveyance mechanism according to Example.

FIG. 8 is a schematic diagram illustrating the orientation changing mechanism according to Example.

FIG. 9 is a flowchart for describing the operation of the substrate processing apparatus according to Example.

FIG. 10 is a schematic diagram illustrating a flow of a substrate in the substrate processing apparatus according to Example.

FIG. 11 is a schematic diagram illustrating a flow of a substrate in the substrate processing apparatus according to Example.

### DESCRIPTION OF EMBODIMENTS

Hereinafter, Example of the present invention will be described with reference to the drawings. A substrate processing apparatus according to Example is configured to acquire substrates in a horizontal orientation stored in a carrier one by one and to eject substrates that have been subjected to various types of substrate processing one by one to the carrier.

### EXAMPLE

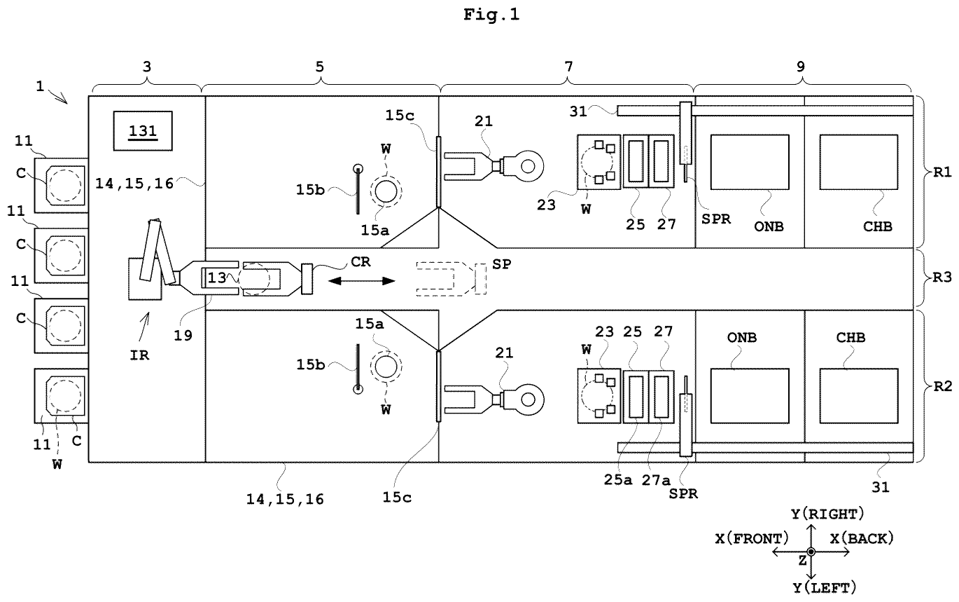

As illustrated in FIG. 1, a substrate processing apparatus 1 of Example is configured by combining a plurality of blocks having different functions. That is, the substrate processing apparatus includes an indexer block 3, a horizontally-oriented substrate processing block 5, an orientation changing block 7, and a vertically-oriented substrate processing block 9.

The substrate processing apparatus 1 performs, for example, each processing such as preliminary chemical liquid processing, main chemical liquid processing, cleaning processing, and drying processing on a substrate W. The preliminary chemical liquid processing is, for example, preliminary etching processing for removing an oxide film grown on a substrate left in air, and the main chemical liquid processing is, for example, main etching processing using phosphoric acid for etching a nitride film. The preliminary chemical liquid processing is substrate processing performed on the substrate W in a horizontal orientation, and the main chemical liquid processing is substrate processing performed on the substrate W whose orientation has been changed into a vertical orientation.

In this specification, for convenience, the directions in which the indexer block 3, the horizontally-oriented substrate processing block 5, the orientation changing block 7, and the vertically-oriented substrate processing block 9 are arrayed are referred to as “front-back directions X”. The front-back directions X extend horizontally. Of the front-back directions X, for example, the direction from the horizontally-oriented substrate processing block 5 toward the indexer block 3 is referred to as “front direction”. The direction opposite to the front direction is referred to as “back direction”. The directions extending horizontally orthogonal to the front-back directions X are referred to as “width directions Y”. One direction of the “width directions Y” is referred to as “right direction” for convenience, and the other direction is referred to as “left direction” for convenience. The directions (height directions) orthogonal to the front-back directions X and the width directions Y are referred to as “vertical directions Z” for convenience. In each drawing, front, back, right, left, up, and down are appropriately shown for reference.

### 1. Indexer Block

The indexer block 3 includes a load port 11 for placing a carrier C that stores a plurality of substrates W in a horizontal orientation at predetermined intervals in a vertical direction. The load port 11 protrudes from the outer wall of the indexer block 3 extending in the width directions (Y directions). In the load port 11, the indexer block 3 unloads the substrate W before cleaning processing from the load port 11, and loads the substrate W after the cleaning processing into the same load port 11. The load port 11 corresponds to a carrier placement shelf of the present invention.

A plurality of (for example, 25) substrates W are stacked and stored in one carrier C at predetermined intervals in a horizontal orientation. The carrier C storing the substrates W to be processed is first placed on the load port 11. The carrier C is formed with a plurality of grooves (not illustrated) extending in the horizontal direction to accommodate the substrates W with their surfaces being separated from each other. One substrate W is inserted into each of the grooves. Examples of the carrier C include a sealed-type front opening unify pod (FOUP). In the present invention, an open type container may be adopted as the carrier C.

The internal structure of the indexer block 3 will be described. As illustrated in FIG. 1, the indexer block 3 includes an indexer robot IR capable of gripping and conveying the substrate W. The indexer robot IR is reciprocable in the Y directions and has a hand that conveys the substrate W. The indexer robot IR includes a hand 19 for gripping the substrate W. The hand 19 can access the load port 11 positioned in front of the indexer robot IR and can access a path 13 of the horizontally-oriented substrate processing block 5 positioned behind the indexer robot IR. Thus, the hand 19 can face the front direction or the back direction. The path 13 is a substrate placing unit for temporarily placing one substrate W in a horizontal orientation.

### 2. Horizontally-Oriented Substrate Processing Block

The horizontally-oriented substrate processing block 5 is positioned behind the indexer block 3. The central portion of the horizontally-oriented substrate processing block 5 in the Y directions includes the above-described path 13 and a center robot CR that can place the substrate W that has been subjected to single wafer processing in the path 13. The horizontally-oriented substrate processing block 5 is provided with a single wafer conveyance region extending in the X directions so that the center robot CR can reciprocate between the path 13 and a reference position SP of the center robot CR set at a position separated from the path 13 in the X directions. The center robot CR can move forward and backward in the X directions in the single wafer conveyance region. The center robot CR corresponds to a substrate handling mechanism and a first substrate conveyance mechanism of the present invention.

The horizontally-oriented substrate processing block 5 includes a single wafer substrate processing chamber 14, a single wafer substrate processing chamber 15, and a single wafer substrate processing chamber 16 capable of performing preliminary chemical liquid processing and drying processing on the substrate W. The plurality of single wafer substrate processing chambers 14, 15, and 16 are provided on the right side and the left side of the single wafer conveyance region. The single wafer substrate processing chamber 14 is positioned below the single wafer substrate processing chamber 15, and the single wafer substrate processing chamber 16 is positioned above the single wafer substrate processing chamber 15. Thus, in FIG. 1, out of the three single wafer substrate processing chambers 14, 15, and 16 stacked in the vertical direction, the intermediate single wafer substrate processing chamber 15 is emphasized.

The reference position SP of the center robot CR is set in the single wafer conveyance region. The reference position SP is positioned away from the path 13 in the X direction. When the center robot CR is at the reference position SP, the center robot CR moves up and down to be able to access each of the single wafer substrate processing chambers 14, 15, and 16.

Each of the single wafer substrate processing chambers 14, 15, and 16 has facing surfaces crossing a flow line of the substrate W connecting each of the single wafer substrate processing chamber 14, the single wafer substrate processing chamber 15, and the single wafer substrate processing chamber 16 to the reference position SP so that the center robot CR can easily access from the reference position SP. A shutter is provided on each of the facing surfaces, and by bringing the shutter into an open state, an opening is formed on the facing surfaces when the substrate W is conveyed from the center robot CR at the reference position SP to each of the single wafer substrate processing chamber 14, the single wafer substrate processing chamber 15, and the single wafer substrate processing chamber 16.

The configuration of the single wafer substrate processing chamber 15 will be described. The single wafer substrate processing chamber 15 can perform substrate drying processing of drying the substrate W by a spin-drying method. A spin chuck 15a that rotates, around a Z axis, the substrate W in a state of being sucked by the spin chuck is provided inside the single wafer substrate processing chamber 15. When the substrate before the drying processing attached to the spin chuck 15a is rotated, the liquid adhering to the substrate W is diffused by the centrifugal force and removed from the substrate W. The single wafer substrate processing chamber 15 according to the present Example also includes a chemical liquid nozzle 15b that supplies a chemical liquid to the substrate W in addition to the configuration to perform the substrate drying processing. The chemical liquid nozzle 15b is turnable between a standby position separated from the spin chuck 15a and a supply position positioned above the spin chuck 15a. The spin chuck 15a is positioned at a lower portion of a predetermined position of the present invention. The substrate W sucked by the spin chuck 15a is at a processing position where chemical liquid processing and drying processing are performed on the substrate W. The single wafer substrate processing chamber 15 is a so-called single wafer type substrate processing chamber that processes the substrates W in a horizontal orientation one by one.

The chemical liquid discharged from the chemical liquid nozzle 15b is, for example, a fluoride such as hydrofluoric acid. When the unprocessed substrate W is processed using the chemical liquid, the oxide film grown on the surface of the substrate W is removed. The oxide film is generated by oxidizing the surface of the substrate W with oxygen contained in the atmosphere. Such an oxide film may adversely affect the production of a device on the substrate, and in such a case, it is necessary to remove the oxide film by chemical processing with the single wafer substrate processing chamber 15.

A horizontally-oriented substrate conveyance mechanism 21 to be described later can access the above-described predetermined position, and can grip and unload the substrate W on the spin chuck 15a from the single wafer substrate processing chamber 15, or place the gripped substrate W on the spin chuck 15a. An openable shutter 15c is provided behind the single wafer substrate processing chamber 15 so that the horizontally-oriented substrate conveyance mechanism 21 can access the predetermined position. When the shutter 15c is in the open state, the horizontally-oriented substrate conveyance mechanism 21 can access the processing position of the single wafer substrate processing chamber 15. When the shutter 15c is in a closed state, chemical liquid processing and drying processing can be performed on the substrate W at the processing position. The horizontally-oriented substrate conveyance mechanism 21 corresponds to a first substrate conveyance mechanism of the present invention.

The single wafer substrate processing chamber 14 and the single wafer substrate processing chamber 16 have the same configuration as that of the single wafer substrate processing chamber 15. The chemical liquid processing (preliminary chemical liquid processing) with the single wafer substrate processing chamber 15 corresponds to a second chemical liquid processing of the present invention, and the chemical liquid discharged from the spin chuck 15a corresponds to a second chemical liquid of the present invention.

### 3. Orientation Changing Block

The orientation changing block 7 is positioned behind the horizontally-oriented substrate processing block 5. On the left side in the Y directions of the orientation changing block 7, there are provided a horizontally-oriented substrate conveyance mechanism 21 that conveys the substrate W that has been subjected to chemical liquid processing by the single wafer substrate processing chamber 15, an orientation changing mechanism 23 that receives the substrate W in a horizontal orientation from the horizontally-oriented substrate conveyance mechanism 21 and changes the orientation of the substrate W from the horizontal orientation to a vertical orientation, a substrate lifting mechanism 27a that receives the substrate W in a vertical orientation from the orientation changing mechanism 23, and a substrate standby tank 27 that immerses the substrate W in a vertical orientation in pure water, for example. The orientation changing mechanism 23 also has a function of changing the orientation of the substrate W that has been subjected to chemical liquid processing by the vertically-oriented substrate processing block 9 described later from a vertical orientation to a horizontal orientation. The horizontally-oriented substrate conveyance mechanism 21 has a function of receiving the substrate W whose orientation has been changed into a horizontal orientation and conveying the substrate W to the processing position of the single wafer substrate processing chamber 15. The substrate lifting mechanism 25a is a mechanism that delivers the substrate W conveyed from the vertically-oriented substrate processing block 9 to the orientation changing mechanism 23. The substrate standby tank 25 is configured to immerse the substrate that has been subjected to chemical liquid processing in the vertically-oriented substrate processing block 9 in pure water, for example.

The horizontally-oriented substrate conveyance mechanism 21, the orientation changing mechanism 23, the substrate standby tank 25, and the substrate standby tank 27 are arrayed in this order in the X directions. The substrate standby tank 25 and the substrate lifting mechanism 25a are at the same position in the XY directions. The substrate standby tank 27 and the substrate lifting mechanism 27a are at the same position in the XY directions. The horizontally-oriented substrate conveyance mechanism 21, the orientation changing mechanism 23, the substrate lifting mechanism 25a, and the substrate lifting mechanism 27a are mechanisms for conveying the substrates W in the single wafer substrate processing chamber 14, the single wafer substrate processing chamber 15, and the single wafer substrate processing chamber 16 positioned on the left side in the Y directions of the horizontally-oriented substrate processing block 5.

On the right side in the Y directions of the orientation changing block 7, similarly to the left side, the horizontally-oriented substrate conveyance mechanism 21, the orientation changing mechanism 23, the substrate standby tank 25, and the substrate standby tank 27 are arrayed in this order in the X directions. The substrate lifting mechanism 25a is provided in the substrate standby tank 25, and the substrate lifting mechanism 27a is provided in the substrate standby tank 27. The horizontally-oriented substrate conveyance mechanism 21, the orientation changing mechanism 23, the substrate lifting mechanism 25a, and the substrate lifting mechanism 27a are mechanisms for conveying the substrates W in the single wafer substrate processing chamber 14, the single wafer substrate processing chamber 15, and the single wafer substrate processing chamber 16 positioned on the right side in the Y directions of the horizontally-oriented substrate processing block 5.

A first region R1 in which the horizontally-oriented substrate conveyance mechanism 21, the orientation changing mechanism 23, the substrate standby tank 25, and the substrate standby tank 27 are arrayed in the X directions is set on the left side in the Y directions of the orientation changing block 7, and a second region R2 in which the horizontally-oriented substrate conveyance mechanism 21, the orientation changing mechanism 23, the substrate standby tank 25, and the substrate standby tank 27 are arrayed in the X directions is set on the right side in the Y directions of the orientation changing block 7. A central region R3 in which the center robot CR is disposed is set at a position sandwiched between the first region R1 and the second region R2.

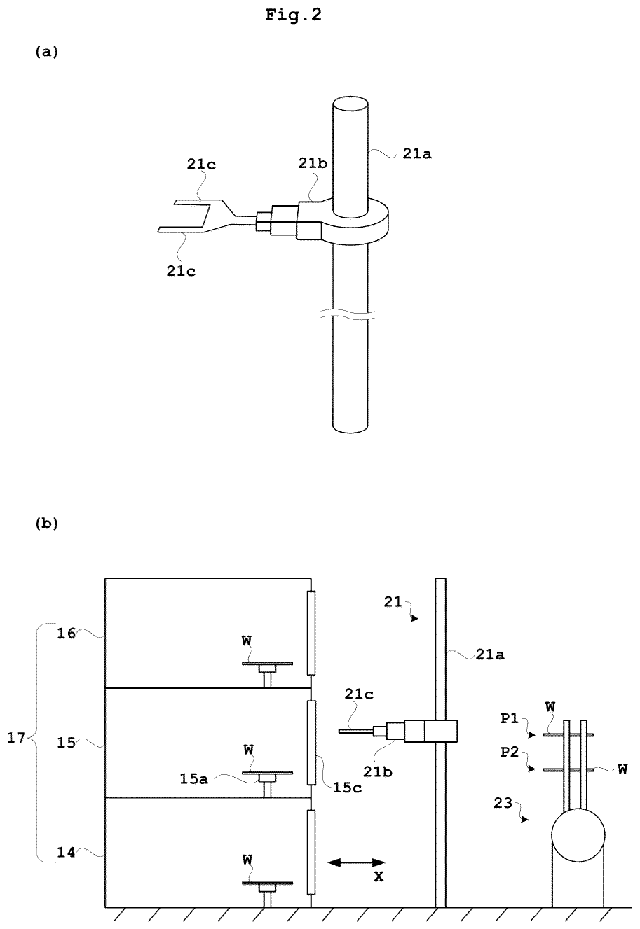

FIG. 2(a) illustrates a specific configuration of the horizontally-oriented substrate conveyance mechanism 21. The horizontally-oriented substrate conveyance mechanism 21 according to the present Example includes a support column 21a extending in a Z direction, a base 21b supported by the support column 21a, and a pair of arms 21c positioned at the distal end of the base 21b. The base 21b can reciprocate in the Z directions in a state of being supported by the support column 21a, whereby the arm 21c moves up and down. In addition, the base 21b can expand and contract in the horizontal directions for the purpose of varying the distance between the arm 21c and the support column 21a. Further, the base 21b can also be rotationally moved about a central axis indicating a direction in which the support column 21a extends for the purpose of making a direction in which the arm 21c is present with respect to the support column 21a variable.

The pair of arms 21c can take two states, a closed state in which the arms are close to each other and an open state in which the arms are separated from each other. When the pair of arms 21c is in the closed state, the substrate W in a horizontal orientation is gripped by the pair of arms 21c. When the pair of arms 21c is in the open state, the gripped substrate W in a horizontal orientation is delivered to, for example, the orientation changing mechanism 23.

FIG. 2(b) illustrates each unit accessible by the horizontally-oriented substrate conveyance mechanism 21. The horizontally-oriented substrate conveyance mechanism 21 can deliver the substrates W to and from the processing position of the single wafer substrate processing chamber 15 (a position held by the spin chuck 15a during substrate processing), for example. The horizontally-oriented substrate conveyance mechanism 21 can deliver the substrates W to and from the processing position of the single wafer substrate processing chamber 14 provided below the single wafer substrate processing chamber 15, or can deliver the substrates W to and from the processing position of the single wafer substrate processing chamber 16 provided above the single wafer substrate processing chamber 15.

In addition, the horizontally-oriented substrate conveyance mechanism 21 can access the first position P1 set in the orientation changing mechanism 23, and can deliver the gripped substrate W in a horizontal orientation to the first position P1. Then, the horizontally-oriented substrate conveyance mechanism 21 can access the second position P2 set in the orientation changing mechanism 23, and can receive and grip the substrate W in a horizontal orientation supported at the second position P2.

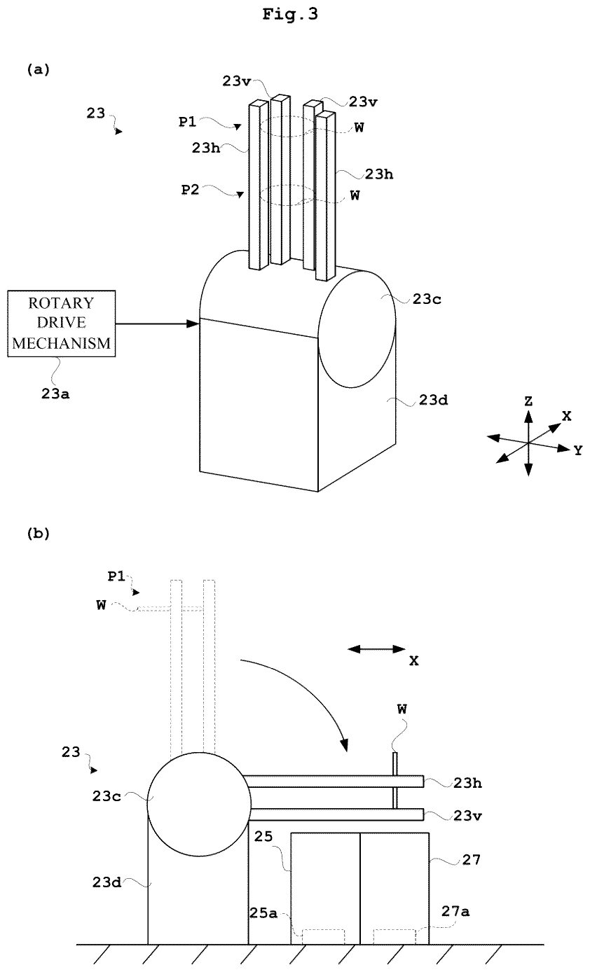

FIG. 3(a) illustrates a specific configuration of the orientation changing mechanism 23. The orientation changing mechanism 23 includes a pair of horizontal holders 23h and a pair of perpendicular holders 23v extending in the longitudinal directions (Z directions). A support body 23c supports the horizontal holder 23h and the perpendicular holder 23v. The base 23d rotatably supports the support body 23c. A rotary drive mechanism 23a is configured to rotate the horizontal holder 23h and the perpendicular holder 23v by 90° together with the support body 23c. With this rotation, the horizontal holder 23h and the perpendicular holder 23v are configured to extend in the left-right directions (Y directions). FIG. 3(b) is a schematic diagram for describing the operation of the orientation changing mechanism 23. Hereinafter, the configuration of each unit will be described with reference to FIG. 3.

The horizontal holder 23h supports the substrate W in a horizontal orientation from below. That is, the horizontal holder 23h has a structure including a recess corresponding to the substrate W to be supported. The recess is an elongated groove in which the peripheral portion of the substrate W is positioned. When the peripheral portion of the substrate W is inserted into the recess, the lower surface of the substrate W in a horizontal orientation comes into contact with the lower end of the recess, and the substrate W is supported in a horizontal orientation.

The perpendicular holder 23v supports the substrate W in a vertical orientation from below. That is, the perpendicular holder 23v has a structure including a V-shaped groove corresponding to the substrate W to be supported. The V-shaped groove has an elongated shape in which the peripheral portion of the substrate W is positioned. When the peripheral portion of the substrate W is inserted into the V-shaped groove, the substrate W is sandwiched by the V-shaped groove and supported in a perpendicular orientation. Since two perpendicular holders 23v are provided on the support body 23c, the substrate W is sandwiched by different V-shaped grooves at two positions of the peripheral portion.

The pair of horizontal holders 23h and the pair of perpendicular holders 23v extending in the vertical directions (Z directions) are provided along a virtual circle corresponding to the substrate W in a horizontal orientation so as to surround the substrate W to be held. The pair of horizontal holders 23h is separated by the diameter of the substrate W, and holds one end of the substrate W and the other end that is the farthest from the one end. In this manner, the pair of horizontal holders 23h supports the substrate W in a horizontal orientation. On the other hand, the pair of perpendicular holders 23v is separated by a distance shorter than the diameter of the substrate W, and supports a predetermined portion of the substrate W and a specific portion positioned in the vicinity of the predetermined portion. In this manner, the pair of perpendicular holders 23v supports the substrate W in a vertical orientation. The pair of horizontal holders 23h is at the same position in the front-back directions (X directions), and the pair of perpendicular holders 23v is at the same position in the front-back directions (X directions). The pair of perpendicular holders 23v is provided on the side in the direction (back direction) in which the support body 23c is rotated and tilted relative to the pair of horizontal holders 23h.

In the orientation changing mechanism 23, the first position P1 is set above and the second position P2 is set below the upright horizontal holder 23h or the like. A recess is provided in a portion corresponding to the first position P1 in the horizontal holder 23h extending in the Z direction, and a V-shaped groove is provided in a portion corresponding to the first position P1 in the perpendicular holder 23v. The recess and V-shaped groove are provided along a virtual circle set at the first position P1. In addition, a recess is provided in a portion corresponding to the second position P2 in the horizontal holder 23h extending in the Z direction, and a V-shaped groove is provided in a portion corresponding to the second position P2 in the perpendicular holder 23v. The recess and V-shaped groove are provided along a virtual circle set at the second position P2. Thus, the orientation changing mechanism 23 can hold the substrate W at the first position P1 and can hold the substrate W at the second position P2 positioned below the first position P1.

The rotary drive mechanism 23a can rotate the support body 23c by at least 90° around a horizontal axis extending in the left-right directions (Y directions). When the support body 23 c in the initial state rotates by 90° with respect to the base 23d, the support body 23c is tilted as illustrated in FIG. 3(b), and the orientation of the substrate W held at the first position P1 is changed from a horizontal orientation to a vertical orientation.

When the support body 23c in the tilted state rotates 90° with respect to the base 23d, the support body 23c returns to the initial state, and can move to the second position P2 while setting the orientation of the substrate W in a vertical orientation received in the tilted state to a horizontal orientation. The substrate W whose orientation has been changed in this manner has already been subjected to the main chemical liquid processing in the vertically-oriented substrate processing block 9.

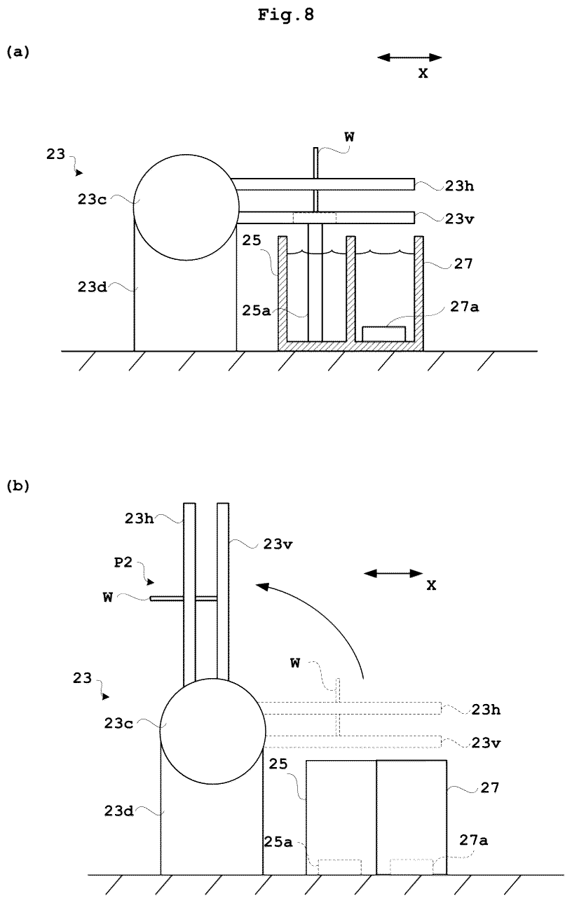

In this manner, the orientation changing mechanism 23 acquires the substrate W going from the horizontally-oriented substrate processing block 5 toward the vertically-oriented substrate processing block 9 at the first position P1. Then, the orientation changing mechanism 23 ejects the substrate W going from the vertically-oriented substrate processing block 9 toward the horizontally-oriented substrate processing block 5 to the second position P2. The orientation changing mechanism 23 selectively uses a substrate holder for the forward path and a substrate holder for the return path so that the forward path and the return path of the substrate W have different paths. The configuration of the orientation changing mechanism 23 in the return path of the substrate W is described with reference to FIG. 8. FIG. 8 will be described later.

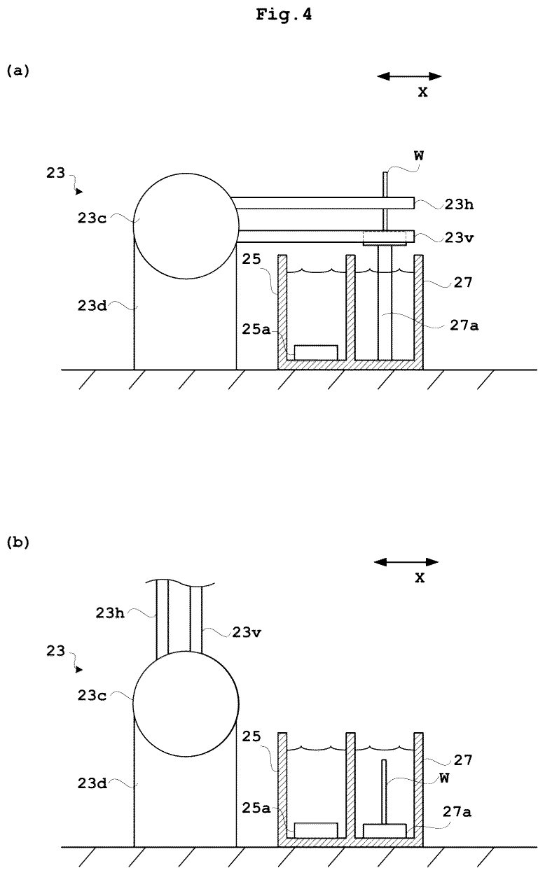

FIG. 4 illustrates the operation of the substrate lifting mechanism 27a. The substrate lifting mechanism 27a can move up and down between a standby position (immersion position) at the bottom of the substrate standby tank 27 and a delivery position above the substrate standby tank 27. The substrate lifting mechanism 27a includes a substrate support that supports the substrate W and a support column having a column shape that moves the substrate support up and down. The substrate support is movable up and down in a state of being supported by the support column. The substrate support is positioned at the bottom surface portion of the substrate standby tank 27 in the initial state. When the substrate W is received from the orientation changing mechanism 23, the substrate support moves up to the delivery position and abuts on the bottom portion of the substrate W supported by the orientation changing mechanism 23 as illustrated in FIG. 4(a).

The substrate standby tank 27 is configured to hold pure water, and can hold one substrate W in a vertical orientation at the immersion position.

The substrate lifting mechanism 27a can further move up from the state of FIG. 4(a). When the substrate lifting mechanism 27a is at the uppermost position, the horizontal holder 23h and the perpendicular holder 23v of the orientation changing mechanism 23 can rotate by 90° without interfering with the substrate lifting mechanism 27a. When the horizontal holder 23h and the perpendicular holder 23v in the orientation changing mechanism 23 stand up to take an orientation extending in the Z directions, the perpendicular holder 23v is retracted from between the substrate standby tank 27 and the substrate support. Thus, the substrate lifting mechanism 27a can convey the substrate W to the immersion position in the substrate standby tank 27 without interfering with the perpendicular holder 23v as illustrated in FIG. 4(b).

The substrate lifting mechanism 25a has the same configuration as the substrate lifting mechanism 27a, and the substrate standby tank 25 has the same configuration as the substrate standby tank 27. That is, the substrate lifting mechanism 27a can move up and down between the standby position (immersion position) at the bottom of the substrate standby tank 27 and the delivery position above the substrate standby tank 27. The substrate support of the substrate lifting mechanism 25a is positioned at the bottom surface portion of the substrate standby tank 25 in the initial state. When the substrate W that has been subjected to the chemical liquid processing in the vertically-oriented substrate processing block 9 is delivered to the orientation changing mechanism 23, the substrate support moves up to the delivery position as illustrated in FIG. 8(a), and abuts the substrate W on the perpendicular holder 23v of the orientation changing mechanism 23.

The substrate standby tank 25 is configured to hold pure water, and can hold one substrate W in a vertical orientation at the immersion position.

The substrate lifting mechanism 25a can further move up from the state of FIG. 8(a). When the substrate lifting mechanism 25a is at the uppermost position, the horizontal holder 23h and the perpendicular holder 23v of the orientation changing mechanism 23 can rotate by 90° without interfering with the substrate lifting mechanism 25a. When the horizontal holder 23h and the perpendicular holder 23v in the orientation changing mechanism 23 stand up to take an orientation extending in the Z directions, the orientation of the substrate W held in the V-shaped groove of the perpendicular holder 23v is changed from a vertical orientation to a perpendicular orientation and abuts on the recess of the horizontal holder 23h. At this time, as illustrated in FIG. 8(b), the substrate W is conveyed from the delivery position above the substrate standby tank 25 to the second position P2.

### 4. Vertically-Oriented Substrate Processing Block

Next, the configuration of the vertically-oriented substrate processing block 9 will be described. As illustrated in FIG. 1, a pure water processing tank ONB and a chemical liquid processing tank CHB are arrayed in the X directions on the left side of the vertically-oriented substrate processing block 9. The pure water processing tank ONB is provided on the orientation changing block 7 side, and the chemical liquid processing tank CHB is disposed at a position separated from the orientation changing block 7. With such a configuration, it is possible to protect a mechanism constituting each robot such as the indexer robot IR from corrosion caused by an acid solution such as phosphoric acid held by the chemical liquid processing tank CHB. The chemical liquid processing tank CHB and the pure water processing tank ONB correspond to a liquid processing tank of the present invention.

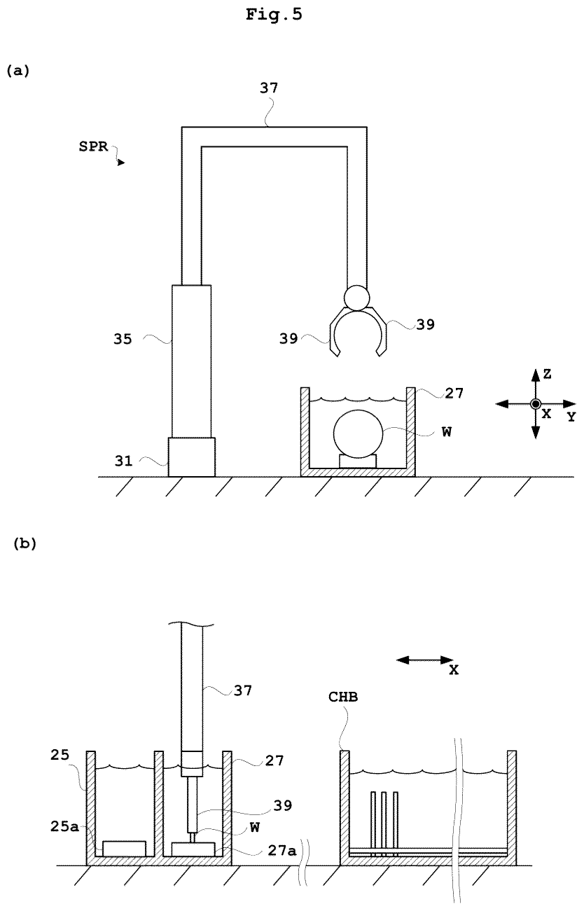

FIGS. 5, 6, and 7 describe the configuration of the vertically-oriented substrate processing block 9. FIG. 5(a) illustrates a vertically-oriented substrate conveyance mechanism SPR in the present Example. The vertically-oriented substrate conveyance mechanism SPR is provided on the left side of the vertically-oriented substrate processing block 9, and is configured to convey the substrate between the substrate standby tank 27, the substrate standby tank 25, the pure water processing tank ONB, and the chemical liquid processing tank CHB positioned on the left side of the substrate processing apparatus 1. The vertically-oriented substrate conveyance mechanism SPR is a mechanism that acquires the substrate W from the substrate standby tank 27 positioned on the left side in the Y directions and conveys the substrate W to the vertically-oriented substrate processing block 9. The vertically-oriented substrate conveyance mechanism SPR is also a mechanism that ejects the substrate from the vertically-oriented substrate processing block 9 to the substrate standby tank 25 positioned on the left side in the Y directions. The vertically-oriented substrate conveyance mechanism SPR corresponds to a second substrate conveyance mechanism of the present invention.

As illustrated in FIG. 5(a), the vertically-oriented substrate conveyance mechanism SPR can reciprocate along a rail 31 extending in the X directions. As can be seen with reference to FIG. 1, the rail 31 extends in the X directions over the substrate standby tank 25 of the orientation changing block 7, the substrate standby tank 27, and the pure water processing tank ONB and the chemical liquid processing tank CHB of the vertically-oriented substrate processing block 9. The vertically-oriented substrate conveyance mechanism SPR includes a base body 35 supported by the rail 31 and extending in the Z directions, a U arm 37 provided at the tip of the base body 35, and a pair of gripping bodies 39 provided at the tip of the U arm 37. The U arm 37 includes a first extension connected to the base body 35 and extending in the Z directions, a second extension provided at the tip of the first extension and extending in the Y directions, and a third extension provided at the tip of the second extension and extending downward in the Z direction. The first extension, the second extension, and the third extension form a U shape as a whole. The U arm 37 can reciprocate in the Z directions with respect to the base body 35.

The pair of gripping bodies 39 can move up and down along with the movement of the U arm 37, and can grip one substrate W in a vertical orientation. The pair of gripping bodies 39 can take two states, a closed state in which the gripping bodies are close to each other and an open state in which the gripping bodies are separated from each other. When the pair of gripping bodies 39 is in the closed state, the substrate W in a vertical orientation is gripped by the pair of gripping bodies 39. When the pair of gripping bodies 39 is in the open state, the gripped substrate W in a vertical orientation is delivered to, for example, the chemical liquid processing tank CHB.

The pair of gripping bodies 39 in the open state can enter the inside of the substrate standby tank 25, the substrate standby tank 27, the chemical liquid processing tank CHB, and the pure water processing tank ONB while maintaining the state. Then, when the pair of gripping bodies 39 comes into the closed state in the substrate standby tank 25, the substrate standby tank 27, the chemical liquid processing tank CHB, and the pure water processing tank ONB, the substrate W in a vertical orientation held at the immersion positions in the respective tanks is gripped by the pair of gripping bodies 39.

The pair of gripping bodies 39 in the closed state can enter the inside of the substrate standby tank 25, the substrate standby tank 27, the chemical liquid processing tank CHB, and the pure water processing tank ONB while maintaining the state. Then, when the pair of gripping bodies 39 comes into the open state in the substrate standby tank 25, the substrate standby tank 27, the chemical liquid processing tank CHB, and the pure water processing tank ONB, the substrate W in a vertical orientation gripped by the pair of gripping bodies 39 is delivered to each tank, and the substrate W is held at the immersion position in each tank.

Similarly to the left side, the pure water processing tank ONB and the chemical liquid processing tank CHB are arranged in this order in the X directions on the right side in the Y directions of the vertically-oriented substrate processing block 9, and the rail 31 extends in the X directions over the substrate standby tank 25 and the substrate standby tank 27 of the orientation changing block 7 and the pure water processing tank ONB and the chemical liquid processing tank CHB of the vertically-oriented substrate processing block 9. The vertically-oriented substrate conveyance mechanism SPR can reciprocate along the rail 31. The vertically-oriented substrate conveyance mechanism SPR is a mechanism that acquires the substrate W from the substrate standby tank 27 positioned on the right side in the Y directions and conveys the substrate W to the vertically-oriented substrate processing block 9. The vertically-oriented substrate conveyance mechanism SPR is also a mechanism that ejects the substrate from the vertically-oriented substrate processing block 9 to the substrate standby tank 25 positioned on the right side in the Y directions.

FIG. 5(b) illustrates a state in which the vertically-oriented substrate conveyance mechanism SPR grips the substrate W held by the substrate lifting mechanism 27a at the immersion position of the substrate standby tank 27. When the vertically-oriented substrate conveyance mechanism SPR receives the substrate W, first, the pair of gripping bodies 39 is moved to a position above the substrate standby tank 27. This operation is realized by moving the vertically-oriented substrate conveyance mechanism SPR in the X direction along the rail 31. Then, the pair of gripping bodies 39 in the open state is lowered and moved to the immersion position of the substrate standby tank 27. This operation is realized by lowering the U arm 37 with respect to the base body 35. Thereafter, by bringing the pair of gripping bodies 39 into the closed state, the vertically-oriented substrate conveyance mechanism SPR grips the substrate W in a vertical orientation at the immersion position of the substrate standby tank 27.

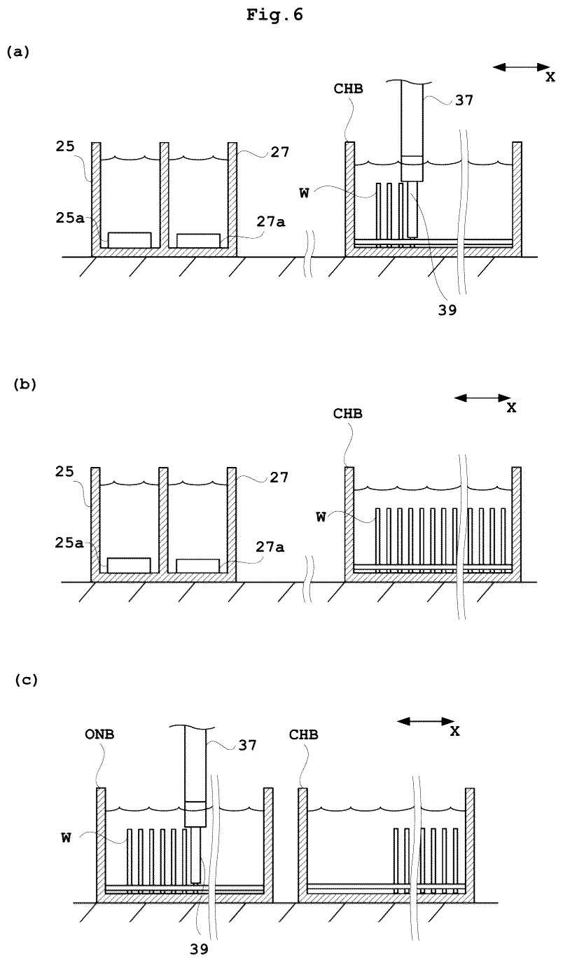

FIG. 6(a) illustrates a state in which the substrate W gripped by the vertically-oriented substrate conveyance mechanism SPR is conveyed to the chemical liquid processing tank CHB. When the vertically-oriented substrate conveyance mechanism SPR delivers the substrate W, first, the pair of gripping bodies 39 gripping the substrate W is moved to a position above the chemical liquid processing tank CHB. This operation is realized by moving the vertically-oriented substrate conveyance mechanism SPR in the X direction along the rail 31. Then, the pair of gripping bodies 39 is lowered and moved to the immersion position to the chemical liquid processing tank CHB. This operation is realized by lowering the U arm 37 with respect to the base body 35. Thereafter, by bringing the pair of gripping bodies 39 into the open state, the vertically-oriented substrate conveyance mechanism SPR conveys the substrate W in a vertical orientation to the chemical liquid processing tank CHB at the immersion position of the chemical liquid processing tank CHB.

In the chemical liquid processing tank CHB, a plurality of substrates W having different loading times can be arrayed in the X directions and held at the immersion position. The chemical liquid processing tank CHB holds an acidic liquid such as phosphoric acid, receives the substrates W in a vertical orientation at the immersion position, and applies phosphoric acid processing (etching processing and main chemical liquid processing) to the substrates W. In the phosphoric acid processing, for example, the nitride film on the surface of the substrates W is chemically etched. Since the phosphoric acid processing takes a long time, for example, about 2 hours, the configuration of the chemical liquid processing tank CHB in which a plurality of substrates W are immersed is advantageous in performing efficient substrate processing. FIG. 6(b) illustrates a state in which all the substrates W stored in the carrier C reach the chemical liquid processing tank CHB, and the phosphoric acid processing is performed on each substrate W. The chemical liquid processing in the chemical liquid processing tank CHB corresponds to a first chemical liquid processing of the present invention, and the chemical liquid held in the chemical liquid processing tank CHB corresponds to a first chemical liquid of the present invention.

FIG. 6(c) illustrates a state in which the substrate W held in the chemical liquid processing tank CHB is gripped by the vertically-oriented substrate conveyance mechanism SPR in the order of completion of the phosphoric acid processing and conveyed to the pure water processing tank ONB. The substrates W held in the chemical liquid processing tank CHB reached the chemical liquid processing tank CHB at a time different from each other. Since the substrate processing apparatus in the present Example is configured to perform the same processing on each substrate W, the end time of the phosphoric acid processing is different for each substrate W. For example, the substrate W (first substrate W) first acquired from the carrier C reaches the chemical liquid processing tank CHB earliest among the respective substrates W, and the substrate W (last substrate W) last acquired from the carrier C reaches the chemical liquid processing tank CHB latest among the respective substrates W. The phosphoric acid processing of each substrate W is completed in the chemical liquid processing tank CHB after the lapse of a first predetermined time. The phosphoric acid processing of the first substrate W is completed at the earliest timing, and the phosphoric acid processing of the last substrate W is completed at the latest timing. In the present Example, when the phosphoric acid processing is completed, the substrate W is loaded into the pure water processing tank ONB. Thus, the first substrate W having finished the phosphoric acid processing is loaded into the pure water processing tank ONB earliest, and the last substrate W having finished the phosphoric acid processing is loaded into the pure water processing tank ONB latest. In this manner, the substrate processing apparatus 1 according to the present Example is configured to sequentially start the phosphoric acid processing over the respective substrates W and sequentially end the phosphoric acid processing in the order in which the first predetermined time has elapsed. The number of substrates W that can be arrayed in the chemical liquid processing tank CHB is, for example, 50.

The pure water processing tank ONB can array a plurality of substrates W having different times of unloading from the chemical liquid processing tank CHB in the X directions and hold the substrates W at the immersion position. The rinse tank holds a rinse liquid such as pure water, receives the substrates W in a vertical orientation at an immersion position, and performs rinse processing on the substrates W for a second predetermined time. The rinse processing of the present Example is configured to sequentially start over each substrate W and sequentially end in the order of the elapse of the second predetermined time, similarly to the above-described phosphoric acid processing. The number of substrates W that can be arrayed in the pure water processing tank ONB is, for example, 50. In general, the second predetermined time is shorter than the first predetermined time. Thus, the number of substrates W that can be arrayed in the pure water processing tank ONB can be made smaller than the number of substrates W that can be arrayed in the chemical liquid processing tank CHB. When the stay time of the substrates W in the pure water processing tank ONB is shorter than the stay time of the substrates W in the chemical liquid processing tank CHB, even when the number of the substrates W held in the pure water processing tank ONB is limited, the substrates W are quickly conveyed to the substrate standby tank 25 without being congested in the pure water processing tank ONB.

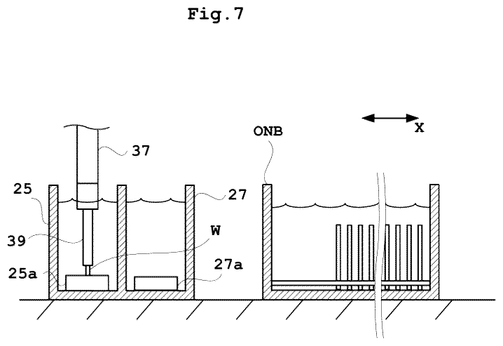

FIG. 7 illustrates the state in which the vertically-oriented substrate conveyance mechanism SPR conveys the substrates W in the pure water processing tank ONB to the substrate standby tank 25 in the order of completion of the rinse processing. In this manner, the vertically-oriented substrate conveyance mechanism SPR that has acquired the substrates W from the substrate standby tank 27 of the orientation changing block 7 conveys the substrates W to the chemical liquid processing tank CHB and the pure water processing tank ONB of the vertically-oriented substrate processing block 9, and ejects the substrates W to the substrate standby tank 25 of the orientation changing block 7.

### 5. Other Configurations

The substrate processing apparatus 1 includes a control unit 131 related to control of the apparatus. Although not illustrated in FIG. 1, a storage unit is provided in the control unit of the substrate processing apparatus 1. The control unit 131 is configured by, for example, a central processing unit (CPU). A specific configuration of the control unit 131 is not limited, and for example, the control unit may be configured by a single processor, or the control unit may be configured by individual processors for respective functions.

Examples of the control related to the control unit 131 include control of the indexer robot IR, the center robot CR, the single wafer substrate processing chamber 14, the single wafer substrate processing chamber 15, the single wafer substrate processing chamber 16, the horizontally-oriented substrate conveyance mechanism 21, the orientation changing mechanism 23, the substrate lifting mechanism 25a, the substrate lifting mechanism 27a, the vertically-oriented substrate conveyance mechanism SPR, and the like.

The storage unit stores programs, parameters, and the like related to control. The storage unit may be configured by a single device or may be configured by individual devices corresponding to the respective processors. The substrate processing apparatus 1 of the present Example has no particular limitation on the configuration of the device that realizes the storage unit.

### 6. Operation of Substrate Processing Apparatus

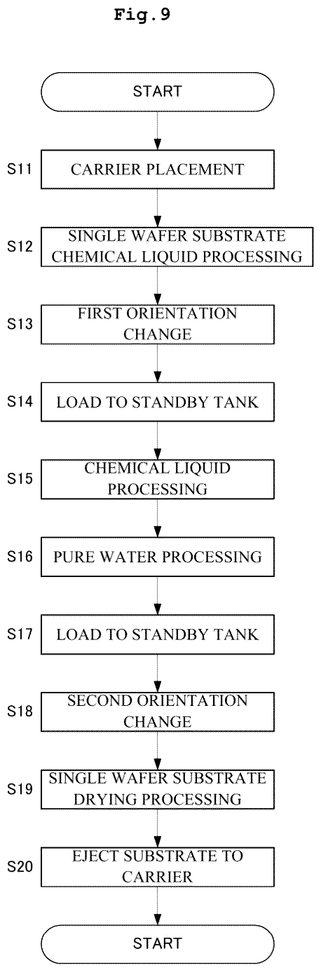

FIG. 9 illustrates the operation of the substrate processing apparatus 1 of the present Example. To perform substrate processing using the substrate processing apparatus 1 of the present Example, the following steps are executed.

Step S11: The carrier C storing the unprocessed substrates W is placed on the load port 11. The indexer robot IR acquires the substrates W in a horizontal orientation one by one from the carrier C, and takes the substrates W into the indexer block 3. The indexer robot IR places the gripped substrate W onto the path 13. The substrates W are thus taken into the horizontally-oriented substrate processing block 5. The center robot CR in the horizontally-oriented substrate processing block 5 acquires the substrate W temporarily placed in the path 13, and unloads the substrate W to any one of the single wafer substrate processing chamber 14, the single wafer substrate processing chamber 15, and the single wafer substrate processing chamber 16. The following description will be given on the assumption that the substrate W at this time is unloaded to the single wafer substrate processing chamber 15 positioned on the left side of the substrate processing apparatus 1. The substrate W loaded into the single wafer substrate processing chamber 15 is conveyed to the center robot CR and is at a processing position (a position where the spin chuck 15a can suck and hold the substrate W)

Step S12: When the rotation of the spin chuck 15a starts, the substrate W held by the spin chuck 15a also starts to rotate. Thereafter, the single wafer substrate processing chamber 15 discharges the chemical liquid from the chemical liquid nozzle toward the substrate W, and starts chemical liquid processing on the substrate surface (the device surface of the substrate W on which a circuit is formed). When the chemical liquid processing of the substrate W is completed, pure water is supplied to the substrate W. The pure water supply source is a pure water supply nozzle having the same configuration as the chemical liquid nozzle.

Step S13: The horizontally-oriented substrate conveyance mechanism 21 acquires the substrate W wetted with pure water from the processing position of the single wafer substrate processing chamber 15, and conveys the substrate W to the first position P1 of the orientation changing mechanism 23. The substrate W is thus conveyed to the orientation changing block 7. The orientation changing mechanism 23 that has acquired the substrate W tilts the horizontal holder 23h and the perpendicular holder 23v by rotating the support body 23c by 90° to change the orientation of the substrate W from a horizontal orientation to a vertical orientation.

Step S14: The orientation changing mechanism 23 conveys the substrate W to the substrate lifting mechanism 27a. The substrate lifting mechanism 27a to which the substrate W has been delivered lowers the substrate W to the immersion position of the substrate standby tank 27. The substrate W waiting in the substrate standby tank 27 is acquired by the vertically-oriented substrate conveyance mechanism SPR and conveyed to the chemical liquid processing tank CHB.

Step S15: A plurality of substrates W are sequentially loaded into the chemical liquid processing tank CHB through the substrate standby tank 27 with a time difference. The plurality of substrates W stored in the carrier C are arrayed at the immersion position in the chemical liquid processing tank CHB, and are subjected to the phosphoric acid processing all together.

Step S16: The vertically-oriented substrate conveyance mechanism SPR takes out the substrates W from the chemical liquid processing tank CHB in the order of completion of the phosphoric acid processing and immerses the substrates W in the pure water processing tank ONB. The substrates W are sequentially loaded into the pure water processing tank ONB from the chemical liquid processing tank CHB with a time difference. The substrates W immersed in the pure water processing tank ONB are rinsed on the spot. Step S16 and the previous step S15 correspond to an immersion liquid processing process of the present invention.

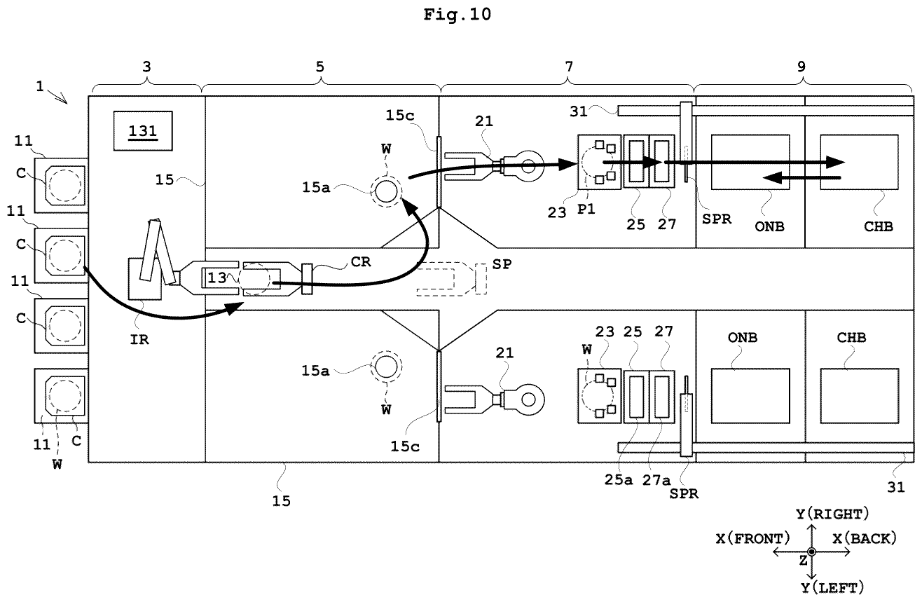

FIG. 10 illustrates substrate conveyance in steps S11 to S16. In FIG. 10, the preliminary chemical liquid processing is performed in the single wafer substrate processing chamber 15 positioned on the left side of the substrate processing apparatus 1, and thus, the substrate W is conveyed by each tank and each mechanism disposed on the left side of the substrate processing apparatus 1. When the preliminary chemical liquid processing is performed in the single wafer substrate processing chamber 15 positioned on the right side of the substrate processing apparatus 1, the substrate W is conveyed to each tank by each mechanism disposed on the right side of the substrate processing apparatus 1, and is subjected to the same processing as each step described above.

Step S17: The vertically-oriented substrate conveyance mechanism SPR unloads the substrates W from the pure water processing tank ONB in order of completion of the rinse processing and immerses the substrates W in the substrate standby tank 25.

Step S18: The substrate lifting mechanism 25a provided in the substrate standby tank 25 lifts the substrates W immersed in the substrate standby tank 25 and delivers the substrates W to the orientation changing mechanism 23. The orientation changing mechanism 23 having received the substrates W changes the orientation of the substrates W to a horizontal orientation by rotating the support body 23c by 90°. Then, the substrate W reaches the second position P2 set in the orientation changing mechanism 23. The horizontally-oriented substrate conveyance mechanism 21 acquires the substrate W before the drying processing at the second position P2, and conveys the substrate W to, for example, the processing position of the single wafer substrate processing chamber 15 (the position where the spin chuck 15a can suck and hold the substrate W). In this step, the substrate W is conveyed to any one of the single wafer substrate processing chamber 14, the single wafer substrate processing chamber 15, and the single wafer substrate processing chamber 16 constituting a stacked body 17.

Step S19: The substrate W is rotated while being held by the spin chuck 15a at the processing position. Then, the moisture adhering to the substrate W is shaken off by the centrifugal force and removed from the substrate W. Thus, the drying processing on the substrate W is completed. The substrate W after the drying processing is held by the center robot CR and conveyed to the path 13.

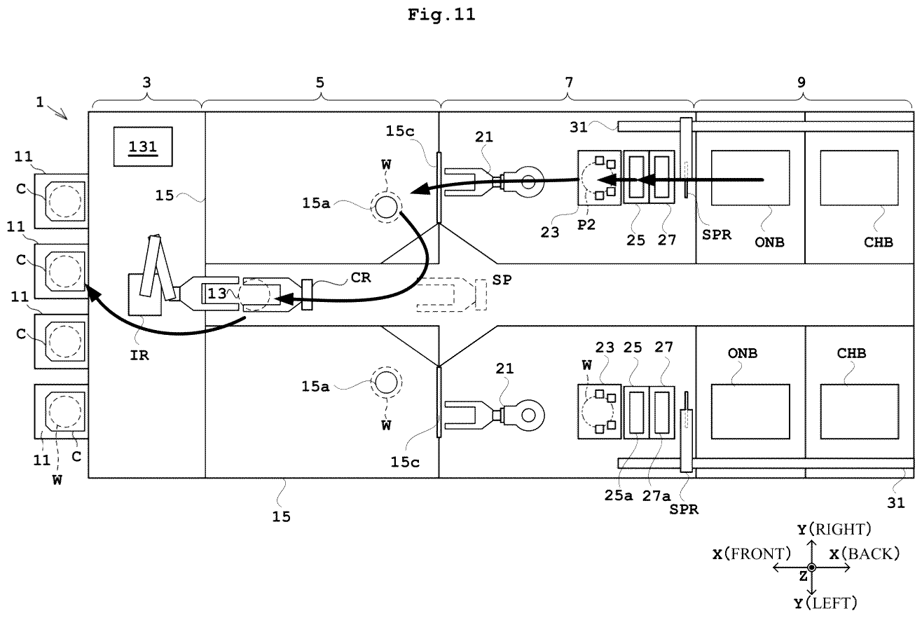

Step S20: The substrate W conveyed to the path 13 is acquired by the indexer robot IR and returned to the original carrier C to which the substrate W has belonged in step S11 (before processing). Thus, the substrate processing according to the present invention is terminated. FIG. 11 illustrates substrate conveyance in steps S17 to S20.

In this manner, according to the configuration of the present invention, a predetermined number of substrates W in a horizontal orientation taken out from the carrier C are conveyed to the orientation changing mechanism 23. The predetermined number of substrates W whose orientation has been changed into a vertical orientation by the orientation changing mechanism 23 are sequentially immersed in the chemical liquid processing tank CHB. The predetermined number of substrates W in a vertical orientation that have been subjected to the liquid processing for the predetermined time are sequentially taken out from the chemical liquid processing tank CHB, subjected to processing in the pure water processing tank ONB, and conveyed to the orientation changing mechanism 23. The orientation of the predetermined number of substrates W in a vertical orientation that have been subjected to the liquid processing is changed into a horizontal orientation by the orientation changing mechanism 23. The predetermined number of substrates W in a horizontal orientation are conveyed to the single wafer substrate processing chamber 15. The predetermined number of substrates W in a horizontal orientation that have been subjected to the drying processing by the single wafer substrate processing chamber 15 are conveyed by the indexer robot IR and stored in the carrier C. Thus, according to the present invention, the predetermined number of substrates W unloaded from the carrier C are sequentially conveyed and subjected to liquid processing and drying processing. Since the substrates W are sequentially immersed in the chemical liquid processing tank CHB without waiting for a long time before liquid processing, the processing histories of the substrates W become uniform, and a highly reliable substrate W processing apparatus can be provided. In addition, in the chemical liquid processing tank CHB, a plurality of substrates W in a vertical orientation are arrayed in a horizontal direction and immersed in the processing liquid. Thus, the plurality of substrates W can be concurrently subjected to liquid processing, and a substrate W processing apparatus with a high throughput can be realized.

The present invention is not limited to the above-described configuration, but can be modified as follows.

### First Modification

The chemical liquid processing tank CHB of the above-described Example has a configuration in which the substrates W in a vertical orientation are arrayed in the X directions, but the present invention is not limited to this configuration. The chemical liquid processing tank CHB may be configured such that the substrates W in a vertical orientation are arrayed in the Y directions. In this case, the second extension of the U arm 37 of the vertically-oriented substrate conveyance mechanism SPR is extendable and contractible in the Y directions, and the pair of gripping bodies 39 can rotate at least 90° about the Z axis about the coupling portion of the gripping body 39. With such a configuration, the existing batch processing tank can be diverted to the chemical liquid processing tank CHB of the present invention. In the pure water processing tank ONB of the present invention, similarly to the chemical liquid processing tank CHB, the substrates W in a vertical orientation may be arrayed in the Y directions.

### Second Modification

In the horizontally-oriented substrate processing block 5 in the above-described Example, the stacked bodies 17 of the substrate processing chambers are provided on the left and right of the center robot CR, but any of the stacked bodies 17 may be omitted. According to the present modification, each tank and each mechanism in the orientation changing block 7 and the vertically-oriented substrate processing block 9 are provided only on the left side or the right side where the stacked body 17 of the substrate processing chamber is installed. With this configuration, the liquid supply source that manages the liquid quality of each tank can be provided on the right side or the left side of the orientation changing block 7 and the vertically-oriented substrate processing block 9 where each tank or each mechanism is not provided.

### Third Modification

In the above-described Example, the pure water processing tank ONB is provided between the substrate standby tank 25 and the chemical liquid processing tank CHB, but the present invention is not limited to this configuration. The functions of the pure water processing tank ONB may be integrated in the substrate standby tank 25, and the pure water processing tank ONB may be omitted.

### Fourth Modification

In the above-described Example, the substrate W going from the horizontally-oriented substrate processing block 5 toward the vertically-oriented substrate processing block 9 is held in the substrate standby tank 27, and the substrate W going from the vertically-oriented substrate processing block 9 toward the horizontally-oriented substrate processing block 5 is held in the substrate standby tank 25. However, the present invention is not limited to this configuration. The substrate W going from the horizontally-oriented substrate processing block 5 toward the vertically-oriented substrate processing block 9 may be held in the substrate standby tank 25, and the substrate W going from the vertically-oriented substrate processing block 9 toward the horizontally-oriented substrate processing block 5 may be held in the substrate standby tank 27. In this case, the horizontally-oriented substrate conveyance mechanism 21 conveys, for example, the substrate W that has been subjected to the preliminary chemical liquid processing acquired in the single wafer substrate processing chamber 15 to the second position P2. Then, the substrate W that has been subjected to the main chemical liquid processing conveyed to the first position P1 is loaded into, for example, the single wafer substrate processing chamber 15.

### Fifth Modification

In the above-described Example, the substrate standby tank 27 in which the substrate W to be conveyed backward is held and the substrate standby tank 25 in which the substrate W to be conveyed forward is held constitute individual tanks. However, the substrate standby tank 27 and the substrate standby tank 25 may be configured as a single tank. The single tank includes two substrate lifting mechanisms, one of which functions as the substrate lifting mechanism 27a and the other one functions as the substrate lifting mechanism 25a. One substrate lifting mechanism may be provided in a single tank, and the substrate lifting mechanism may have the function of the substrate lifting mechanism 27a and the function of the substrate lifting mechanism 25a. In this case, the horizontally-oriented substrate conveyance mechanism 21 conveys, for example, the substrate W that has been subjected to hydrofluoric acid processing acquired in the single wafer substrate processing chamber 15 to the first position P1. Then, the substrate W that has been subjected to phosphoric acid processing and conveyed to the first position P1 is loaded into, for example, the single wafer substrate processing chamber 15.

### Sixth Modification

In the above-described Example, the single wafer substrate processing chamber 14, the single wafer substrate processing chamber 15, and the single wafer substrate processing chamber 16 perform the preliminary chemical liquid processing in the horizontally-oriented substrate processing block 5. However, the present invention is not limited to this configuration, and the preliminary chemical liquid processing may be omitted. In this case, the single wafer substrate processing chamber 14, the single wafer substrate processing chamber 15, and the single wafer substrate processing chamber 16 are not limited as long as they can perform substrate drying processing. The substrates W placed by the center robot CR at the processing positions of the single wafer substrate processing chamber 14, the single wafer substrate processing chamber 15, and the single wafer substrate processing chamber 16 are not subjected to substrate processing by the single wafer substrate processing chamber 14, the single wafer substrate processing chamber 15, or the single wafer substrate processing chamber 16, but are received by the horizontally-oriented substrate conveyance mechanism 21.

### Seventh Modification

In the sixth modification, the center robot CR may directly convey the substrate W to the orientation changing mechanism 23 without passing through the single wafer substrate processing chamber 15.

### Eighth Modification

In the above-described Example, the stacked body 17 including the single wafer substrate processing chamber 14, the single wafer substrate processing chamber 15, and the single wafer substrate processing chamber 16 is provided, but the present invention is not limited to this configuration. The horizontally-oriented substrate processing block 5 can also be configured to have one single wafer substrate processing chamber 15 in the Z direction.

### Ninth Modification

The indexer robot IR of the above-described Example is configured to acquire and eject one substrate W from the carrier C, but the present invention is not limited to this configuration. The indexer robot IR may be configured to acquire and eject a plurality of substrates W from the carrier C. Similarly, the center robot CR, the horizontally-oriented substrate conveyance mechanism 21, and the vertically-oriented substrate conveyance mechanism SPR may be configured such that a plurality of substrates W can be conveyed.

### Tenth Modification

The orientation changing mechanism 23 of the above-described Example receives the substrates W one by one to change the orientation, but the present invention is not limited to this configuration. A plurality of substrates W may be received from the horizontally-oriented substrate conveyance mechanism 21, and the orientation of the substrates W may be collectively changed. Similarly, a plurality of substrates W may be received from the substrate lifting mechanism 25a, and the orientation of the substrates W may be collectively changed. In the case of the present modification, the substrate lifting mechanism 27a may be configured to array and hold the substrates Win a vertical orientation in the X directions, or the substrate lifting mechanism 25a may be configured to array and hold the substrates W in a vertical orientation in the X directions.

### REFERENCE SIGNS LIST

1 substrate processing apparatus
3 indexer block
5 horizontally-oriented substrate processing block
7 orientation changing block
9 vertically-oriented substrate processing block
11 load port (carrier placement shelf)
13 path
14 single wafer substrate processing chamber
15 single wafer substrate processing chamber
15a spin chuck
15b chemical liquid nozzle
15c shutter
16 single wafer substrate processing chamber
19 hand
21 horizontally-oriented substrate conveyance mechanism (first substrate conveyance mechanism)
21a support column
21b base
21c arm
23 orientation changing mechanism
23a rotary drive mechanism
23c support body
23d base
23h horizontal holder
23v perpendicular holder
25 substrate standby tank
25a substrate lifting mechanism
27 substrate standby tank
27a substrate lifting mechanism
31 rail
35 base body
37 U arm
39 gripping body
131 control unit
C carrier
CHB chemical liquid processing tank (liquid processing tank)
CR center robot (substrate handling mechanism, first substrate conveyance mechanism)
IR indexer robot
ONB pure water processing tank (liquid processing tank)
SP reference position
SPR vertically-oriented substrate conveyance mechanism (second substrate conveyance mechanism)
P1 first position
P2 second position
R1 first region
R2 second region
R3 central region
W substrate

1. A substrate processing apparatus that continuously performs a series of processing while changing an orientation of a substrate, the substrate processing apparatus comprising:
a carrier placement shelf on which a carrier that stores a plurality of substrates in a horizontal orientation at predetermined intervals in a vertical direction is placed;
an indexer robot that takes out and stores a predetermined number of substrates from and in the carrier;
an orientation changing mechanism that changes the orientation of a predetermined number of substrates into a horizontal orientation and a vertical orientation;
a liquid processing tank in which a plurality of substrates in the vertical orientation are arrayed in a horizontal direction and immersed in a processing liquid;
a single wafer substrate processing chamber that performs drying processing on substrates in the horizontal orientation one by one by rotating the substrates in the horizontal orientation around a vertical axis;
a first substrate conveyance mechanism that conveys the predetermined number of substrates in the horizontal orientation between the indexer robot, the orientation changing mechanism, and the single wafer substrate processing chamber;
a second substrate conveyance mechanism that conveys the predetermined number of substrates in the vertical orientation between the orientation changing mechanism and the liquid processing tank; and
a control unit,
wherein
the control unit controls the indexer robot to take out the predetermined number of substrates from the carrier,
the control unit controls the first substrate conveyance mechanism to convey the predetermined number of substrates taken out from the carrier to the orientation changing mechanism,
the control unit controls the orientation changing mechanism to change the orientation of the predetermined number of substrates in the horizontal orientation into the vertical orientation,
the control unit controls the second substrate conveyance mechanism to sequentially immerse the predetermined number of substrates whose orientation has been changed into the vertical orientation in the liquid processing tank, the control unit controls the second substrate conveyance mechanism to
sequentially take out the predetermined number of substrates in the vertical orientation that have been subjected to liquid processing for a predetermined time from the liquid processing tank and convey the substrates to the orientation changing mechanism,
the control unit controls the orientation changing mechanism to change the orientation of the predetermined number of substrates in the vertical orientation that have been subjected to liquid processing into the horizontal orientation,
the control unit controls the first substrate conveyance mechanism to convey the predetermined number of substrates in the horizontal orientation to the single wafer substrate processing chamber,
the control unit controls the single wafer substrate processing chamber to rotate the substrates in the horizontal orientation about a vertical axis to dry the substrates one by one,
the control unit controls the first substrate conveyance mechanism to cause the indexer robot to convey the predetermined number of substrates in the horizontal orientation that have been subjected to drying processing, and
the control unit controls the indexer robot to store the predetermined number of substrates in the horizontal orientation that have been subjected to drying processing in the carrier.

2. The substrate processing apparatus according to claim 1, wherein
the indexer robot is provided in the indexer block,
the orientation changing mechanism is provided in the orientation changing block,
the liquid processing tank is provided in the vertically-oriented substrate processing block,
the single wafer substrate processing chamber is provided in the horizontally-oriented substrate processing block,
the indexer block is adjacent to the carrier placement shelf,
the horizontally-oriented substrate processing block is adjacent to the indexer block on a side opposite to a side on which the carrier placement shelf is in contact,
the orientation changing block is adjacent to the horizontally-oriented substrate processing block on a side opposite to a side on which the indexer block is in contact, and
the vertically-oriented substrate processing block is adjacent to the orientation changing block on a side opposite to a side on which the horizontally-oriented processing block is in contact.

3. The substrate processing apparatus according to claim 2, wherein
a substrate handling mechanism and a horizontally-oriented substrate conveyance mechanism are provided as the first substrate conveyance mechanism,
the substrate handling mechanism delivers the predetermined number of substrates between the indexer robot and the horizontally-oriented substrate processing block,
the horizontally-oriented substrate conveyance mechanism is provided in the orientation changing block, and delivers the predetermined number of substrates between the horizontally-oriented substrate processing block and the orientation changing mechanism,
when sending the substrates to the liquid processing tank,
the control unit controls the substrate handling mechanism to convey the predetermined number of substrates taken out from the carrier by the indexer robot to the horizontally-oriented substrate processing block, and
the control unit controls the horizontally-oriented substrate conveyance mechanism to cause the orientation changing mechanism to convey the predetermined number of substrates conveyed to the horizontally-oriented substrate processing block,
when returning the substrates from the liquid processing tank,
the control unit controls the horizontally-oriented substrate conveyance mechanism to convey the predetermined number of substrates whose orientation has been changed into the horizontal orientation by the orientation changing mechanism to the single wafer substrate processing chamber, and
the control unit controls the substrate handling mechanism to cause the indexer robot to convey the predetermined number of substrates in the horizontal orientation that have been subjected to drying processing by the single wafer substrate processing chamber.

4. The substrate processing apparatus according to claim 2, wherein the orientation changing block includes:
a first substrate standby tank for a forward path in which the predetermined number of substrates in the vertical orientation before liquid processing are immersed in pure water;
a second substrate standby tank for a return path in which the predetermined number of substrates in the vertical orientation after liquid processing are immersed in pure water; and
a substrate lifting mechanism capable of delivering the substrates between the orientation changing mechanism and the second substrate conveyance mechanism and capable of lifting the predetermined number of substrates in the vertical orientation between a delivery position of the substrate and a standby position in the first and second substrate standby tanks,
when sending the substrates to the liquid processing tank,
the control unit controls the substrate lifting mechanism to cause the predetermined number of substrates whose orientation has been changed into the vertical orientation by the orientation changing mechanism to be immersed in pure water in the first substrate standby tank and stand by, and
when returning the substrates from the liquid processing tank,
the control unit controls the substrate lifting mechanism to receive the predetermined number of substrates in the vertical orientation that have been subjected to liquid processing from the second substrate conveyance mechanism, and causes the predetermined number of substrates in the vertical orientation to be immersed in pure water in the second substrate standby tank and stand by.

5. The substrate processing apparatus according to claim 2, wherein
the vertically-oriented substrate processing block includes, as the liquid processing tank, a chemical liquid processing tank containing a chemical liquid and a pure water processing tank containing pure water,
the control unit controls the second substrate conveyance mechanism to sequentially immerse the predetermined number of substrates whose orientation has been changed into the vertical orientation in the chemical liquid processing tank,
the control unit controls the second substrate conveyance mechanism to sequentially take out the predetermined number of substrates in the vertical orientation that have been subjected to chemical liquid processing for a predetermined time from the chemical liquid processing tank, and then convey the substrates to the pure water processing tank and sequentially immerse the substrates in the pure water processing tank, and
the control unit controls the second substrate conveyance mechanism to sequentially take out the predetermined number of substrates in the vertical orientation that have been subjected to pure water processing and convey the substrates to the orientation changing block.

6. The substrate processing apparatus according to claim 2, wherein the horizontally-oriented substrate processing block includes a stacked body formed by stacking the single wafer substrate processing chambers in a vertical direction.

7. The substrate processing apparatus according to claim 2, wherein the single wafer substrate processing chamber rotates the substrates in the horizontal orientation about a vertical axis and performs chemical liquid processing on the substrates one by one before the drying processing.

8. The substrate processing apparatus according to claim 2, the substrate processing apparatus comprising:
a first region that is adjacent to the indexer block on a side opposite to a side on which the carrier placement shelf is in contact and extends in a direction away from the indexer block; and
a second region facing the first region, adjacent to the indexer block, and extending in a direction away from the indexer block,
wherein
in the first region, the first horizontally-oriented substrate processing block, the first orientation changing block, and the first vertically-oriented substrate processing block are disposed linearly,
in the second region, the second horizontally-oriented substrate processing block, the second orientation changing block, and the second vertically-oriented substrate processing block are disposed linearly,
the substrate handling mechanism is disposed in a central region between the first region and the second region and in contact with the indexer block, and
the substrate handling mechanism delivers the substrates to and from each of the first horizontally-oriented substrate processing block and the second horizontally-oriented substrate processing block.

9. A substrate processing method for continuously performing a series of processing while changing an orientation of a substrate, the substrate processing method comprising:
a first orientation changing process of changing an orientation of a predetermined number of substrates from a horizontal orientation to a vertical orientation;
an immersion liquid processing process of sequentially immersing the predetermined number of substrates in the vertical orientation in a processing liquid in a liquid processing tank to perform liquid processing with a plurality of substrates in the vertical orientation being arrayed in a horizontal direction in the liquid processing tank;
a second orientation changing process of sequentially taking out the predetermined number of substrates in the vertical orientation that have been subjected to the liquid processing for a predetermined time from the liquid processing tank and changing the orientation of the predetermined number of substrates from the vertical orientation to the horizontal orientation; and
a single wafer substrate drying processing process of rotating the substrates in the horizontal orientation about a vertical axis to dry the substrates one by one.

10. The substrate processing method according to claim 9, wherein
the immersion liquid processing process includes:
a chemical liquid processing process of sequentially immersing the predetermined number of substrates in the vertical orientation in the chemical liquid in the chemical liquid processing tank to perform chemical liquid processing with a plurality of substrates in the vertical orientation being arrayed in the horizontal direction; and
a pure water processing process of immersing the predetermined number of substrates in the vertical orientation taken out from the chemical liquid processing tank into pure water in a pure water processing tank to perform pure water processing with a plurality of substrates in the vertical orientation being arrayed in the horizontal direction.

11. The substrate processing method according to claim 9, the method further comprising a single wafer substrate chemical liquid processing process of processing substrates one by one by rotating the substrates in the horizontal orientation about a vertical axis before the single wafer substrate drying processing process.
